(19) United States
(12) Patent Application Publication
(10) Pub. No.: US 2025/0303571 A1
(43) Pub. Date: Oct. 2, 2025

(54) MONITORING SYSTEM

(71) Applicant: KAWASAKI JUKOGYO KABUSHIKI KAISHA, Kobe-shi (JP)

(72) Inventors: Takuya Ichise, Kobe-shi (JP); Sosuke Abe, Kobe-shi (JP); Ryohei Yamauchi, Kobe-shi (JP)

(73) Assignee: KAWASAKI JUKOGYO KABUSHIKI KAISHA, Kobe-shi (JP)

(21) Appl. No.: 19/090,857

(22) Filed: Mar. 26, 2025

(30) Foreign Application Priority Data
Mar. 27, 2024 (JP) 2024-051891

(51) Int. Cl. B25J 9/16; G01R 19/00

(52) U.S. Cl. CPC B25J 9/1674; G01R 19/0038

(57) ABSTRACT

The monitoring system includes: locators that each have an arm moved by a motor and align, at the respective positions, a workpiece conveyed to a work area; and a monitoring device that calculates a comparison value for each of the locators by comparing a current value supplied to the motor with a representative value set for each of the locators and associated with the current value.

### CROSS-REFERENCE TO RELATED APPLICATION

This application claims priority to Japanese Patent Application No. 2024-51891 filed on Mar. 27, 2024, the entire disclosure of which is incorporated herein by reference.

### BACKGROUND

The technology disclosed herein relates to a monitoring system.

A conventional assembly line includes multi-axis robots that align an underbody and an AGV that carries the underbody into an assembly area. The multi-axis robots each lift the underbody from below and hold it at a predetermined height.

### SUMMARY

For motor-driven robots, acquiring the load on the motor is useful for grasping the operation state of the motor. However, when a workpiece is supported by robots such as in a conventional assembly line, the load on each of the robots changes depending on the shape or posture of the workpiece. It is thus difficult to grasp the cause of the change in load on the motor simply by acquiring the load on the motor independently for each robot.

The technology disclosed herein relates to a monitoring system. The monitoring system includes: locators that each have an arm moved by a motor and align, at the respective positions, a workpiece conveyed to a work area; and a monitoring device that calculates a comparison value for each of the locators by comparing a current value supplied to the motor with a representative value set for each of the locators and is associated with the current value.

### BRIEF DESCRIPTION OF THE DRAWINGS

FIG. 1 shows a robot system applied to a manufacturing line of an automobile.

FIG. 2 shows the robot system.

FIG. 3 shows a block diagram of the robot system.

FIG. 4 is a schematic view of a locator.

FIG. 5 is a schematic view of a monitoring system.

FIG. 6 is a schematic view of a screen of a display device.

FIG. 7 is a flowchart illustrating a process of acquiring a representative value by the monitoring system.

FIG. 8 is a flowchart illustrating a process of monitoring a comparison value by the monitoring system.

FIG. 9 is a flowchart illustrating a process of monitoring a comparison value by a monitoring system according to a first variation.

FIG. 10 is a flowchart illustrating a process of monitoring a comparison value by a monitoring system according to a second variation.

### DETAILED DESCRIPTION OF THE DRAWINGS

Embodiments of the monitoring system will be described below with reference to the drawings. The monitoring system described herein is exemplary.

### (Overall Structure of Robot System)

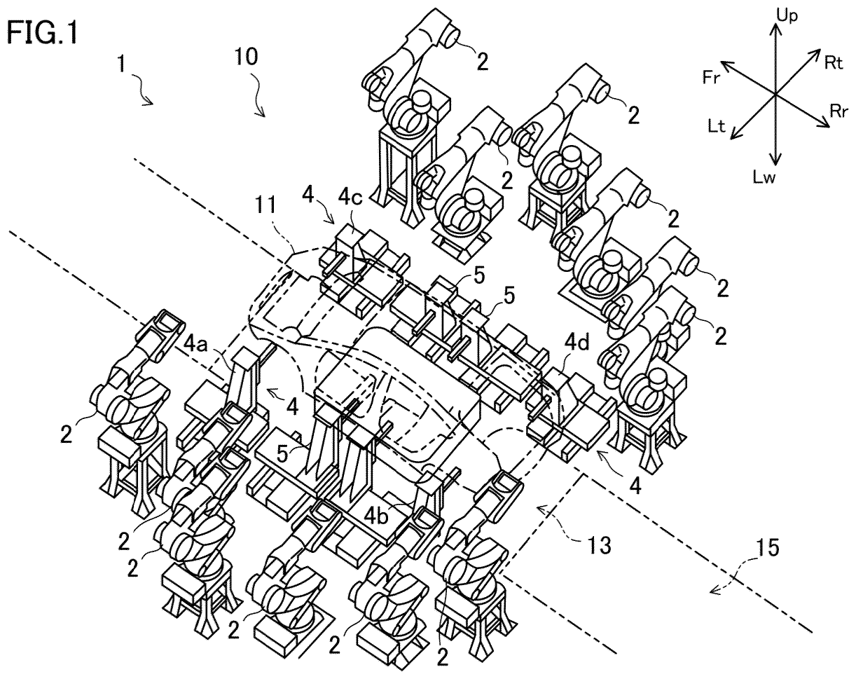

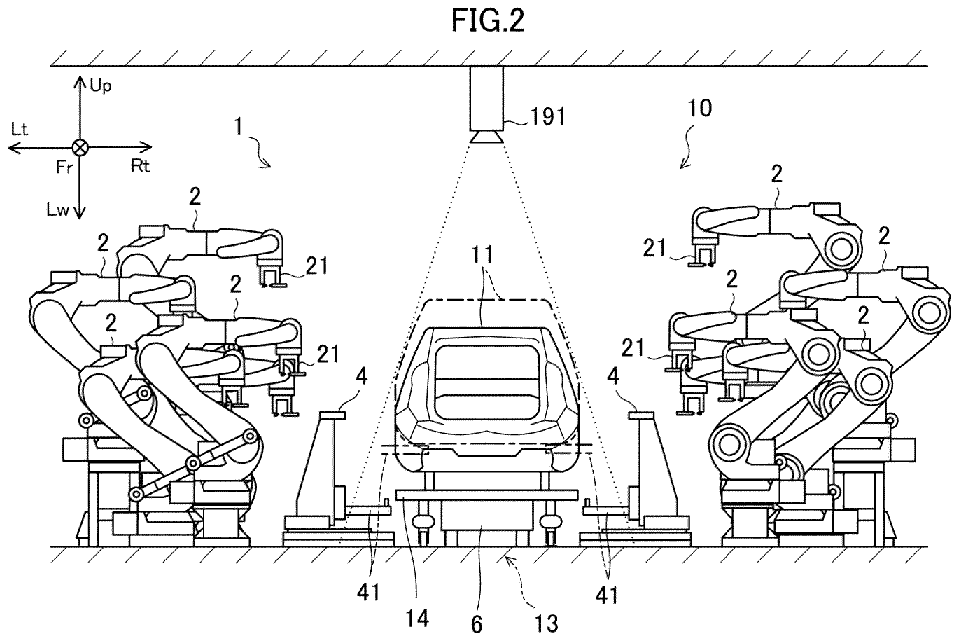

FIG. 1 is a perspective view of a robot system 1 to which a monitoring system is applied, as viewed obliquely from above. FIG. 2 is a back view of the robot system 1 as viewed from the rear. The robot system 1 is applied to a manufacturing line 10 in a factory for automobiles. In the manufacturing line 10 illustrated in FIG. 1, welding, more specifically, spot welding is performed on a body 11 of an automobile. The body 11 is an example of a workpiece.

In the robot system 1, the front Fr, the rear Rr, the right Rt, the left Lt, the upper Up, and the lower Lw are defined as follows with reference to the body 11, which is a work target of the robot system 1.

The front Fr of the robot system 1 is a rear left side in a direction connecting a front right side and a rear left side on the paper in FIG. 1. The front Fr of the robot system 1 corresponds to the front of the body 11 of the automobile, and the rear Rr of the robot system 1 corresponds to the rear of the body 11 of the automobile.

The right Rt of the robot system 1 is a rear right side in a direction connecting a front left side and a rear right side on the paper. The right Rt of the robot system 1 corresponds to the right of the body 11 of the automobile. The left Lt of the robot system 1 is a front left side in a direction connecting a front left side and a rear right side on the paper. The left Lt of the robot system 1 corresponds to the left of the body 11 of the automobile.

The upper Up of the robot system 1 is the upper side on the paper, and the lower Lw of the robot system 1 is the lower side on the paper. The upper and lower sides of the robot system 1 correspond to the upper and lower sides of the body 11 of the automobile.

The above definitions are definitions used for describing the robot system 1, and are not used for limiting the structures and configurations of the robot system 1 disclosed herein and the elements included in the robot system 1.

The robot system 1 includes a robot 2. The robot 2 performs work on the workpiece conveyed to the work area 13. The work area 13 is an area which is located on a conveyance path 15 of an autonomous mobile robot (AMR) 6 and in which the workpiece of the robot 2 is located by stopping the AMR 6. The workpiece for the robot 2 is a body 11. The work performed on the body 11 of the robot 2 is welding.

The robot 2 is a 5-axis, 6-axis or 7-axis vertical articulated robot. As illustrated in FIG. 2, the robot 2 has a welding gun 21 as an end effector. The robot 2 is not limited to the vertical articulated robot.

The robot system 1 includes robots 2. The robot system 1 shown in FIG. 2 includes twelve robots 2. The twelve robots 2 are located on the left and right sides of the body 11. On the right side of the body 11, six robots 2 are arranged in the front-rear direction of the body. On the left side of the body 11, six robots 2 are arranged in the front-rear direction of the body. The robots 2 perform welding at the respective locations on the body 11. The number of robots 2 in the robot system 1 is not limited to a particular number. The robots 2 in the robot system 1 are also not limited to be arranged at particular locations.

The robot system 1 includes at least one locator 4. As illustrated by a dashed line in FIG. 2, the locator 4 supports the body 11 during the work of the robot 2. The locator 4 aligns the body 11 while supporting the body 11. A detailed configuration of the locator 4 will be described later.

The robot system 1 includes locators 4. The robot system 1 shown in FIG. 2 includes four locators 4. The four locators 4 are located on the left and right sides of the body 11. On the left side of the body 11, two locators 4 are arranged in the front-rear direction of the body. One of the two locators 4 supports a front left end of the body 11, and the other locator 4 supports a rear left end of the body 11. On the right side of the body 11, two locators 4 are arranged in the front-rear direction of the body. One of the two locators 4 supports a front right end of the body 11, and the other locator 4 supports a rear right end of the body 11. Hereinafter, the locator 4 disposed on the front left side is referred to as a first locator 4a, the locator 4 disposed on the rear left side is referred to as a second locator 4b, the locator 4 disposed on the front right side is referred to as a third locator 4c, and the locator 4 disposed on the rear right side is referred to as a fourth locator 4d. When it is not necessary to distinguish between the four locators 4, they are simply referred to as locators 4. The first locator 4a, second locator 4b, third locator 4c, and fourth locator 4d have the same configuration except for the arrangement.

The first locator 4a and the third locator 4c are located in the same position in the front-rear direction. The second locator 4b and the fourth locator 4d are located in the same position in the front-rear direction.

The robot system 1 includes at least one support device 5. The support device 5 supports the body 11 during the work of the robot 2. The support device 5 is not an essential element of the robot system 1.

The robot system 1 includes support devices 5. The robot system 1 shown in FIG. 2 includes four support devices 5. The four support devices 5 are located on the left and right sides of the body 11. On the left side of the body 11, two support devices 5 are arranged in the front-rear direction of the body between the first locator 4a and the second locator 4b. The two support devices 5 support the front left center of the body 11. Similarly, on the right side of the body 11, two support devices 5 are arranged in the front-rear direction of the body 11 between the third locator 4c and the fourth locator 4d. The two support devices 5 support the front right center of the body 11.

The configuration of each of the support devices 5 is the same as that of the locator 4. Each support device 5 has an arm that supports the body 11 from below. In this embodiment, each support device 5 does not align the body 11 and merely supports the body 11 from below. Each support device 5 may be used as a locator. For example, when the size of the workpiece in the front-rear direction is small, the support device 5 is used as a locator and aligns the workpiece.

The robot system 1 includes one or multiple carriers. The carrier conveys the workpiece to the work area 13. The carrier is an autonomous mobile robot (AMR) 6. The AMR 6 travels on the flat floor in a factory. As illustrated in FIG. 2, the body 11 is placed on a carriage 14. The AMR 6 is located below the carriage 14 and engages the carriage 14. The AMR 6 conveys the body 11 via the carriage 14. The AMR 6 may directly support the body 11 without the carriage 14. The appearance of the AMR 6 shown in FIGS. 1 and 2 is exemplary.

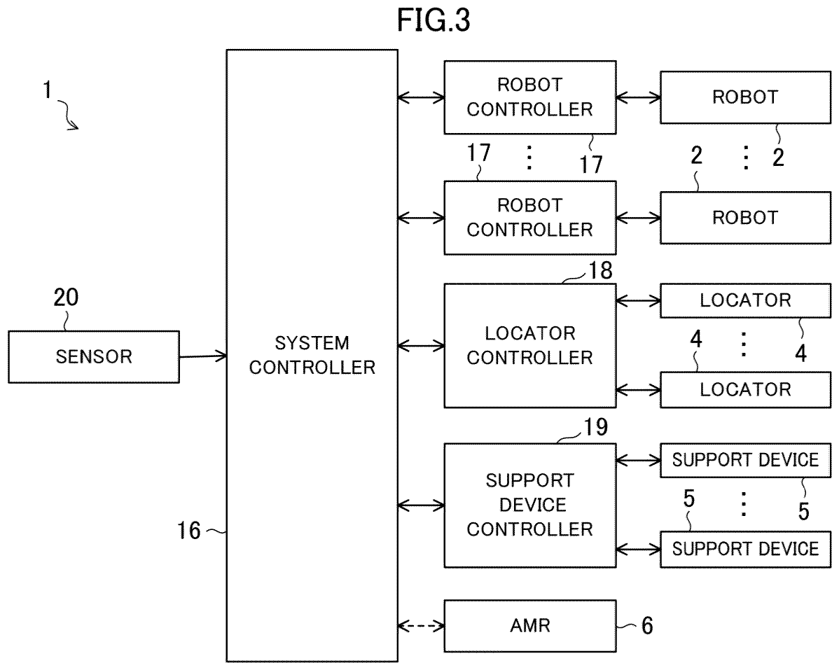

FIG. 3 is a block diagram of the robot system 1. The robot system 1 includes a system controller 16. The system controller 16 is not an essential element of the robot system 1. The system controller 16 controls the entire robot system 1.

The robot system 1 includes robot controllers 17. The robot controllers 17 are not essential elements of the robot system 1. The robot controllers 17 are electrically connected to the system controller 16. The electrical connection includes wired or wireless connection. The robot controllers 17 are also electrically connected to the respective robots 2. The robot controller 17 and the robot 2 is connected one-on-one. The robot system 1 includes the robot controllers 17, the number of which is the same as the number of robots 2. The number of robot controllers 17 may be smaller than the number of robots 2.

The robot controllers 17 controls the respective robots 2. More specifically, the robot controller 17 receives a control signal from the system controller 16 and outputs the control signal to the robot 2. The robot 2 receives the control signal from the robot controller 17 and performs welding on the body 11.

The robot system 1 includes a locator controller 18. The locator controller 18 is not an essential element of the robot system 1. The locator controller 18 is electrically connected to the system controller 16. The electrical connection includes wired or wireless connection. The locator controller 18 is electrically connected to the locators 4.

The locator controller 18 controls the locators 4. More specifically, the locator controller 18 receives a control signal from the system controller 16 and outputs the control signal to the locators 4. The locators 4 receive the control signal from the locator controller 18 and align and support the body 11 carried by the AMR 6 in a predetermined position.

The robot system 1 includes a sensor 20. The sensor 20 is electrically connected to the system controller 16. The sensor 20 includes an external camera 191 to be described later.

The external camera 191 is located above the work area 13 as illustrated in FIG. 2. The external camera 191 captures an image of the body 11 located in the work area 13. The image captured by the external camera 191 is sent to the system controller 16. The system controller 16 determines the degree of the tilt of the body 11 in the horizontal plane on the basis of the image captured by the external camera 191.

### (Configuration of Locator)

The locators 4 are each a 3-axis orthogonal robot. The locator 4 has an arm 41 that supports the body 11 from below. The arm 41 extends in the left-right direction. The arm 41 has a pin 41a at the distal end. The pin 41a is connected to the body 11.

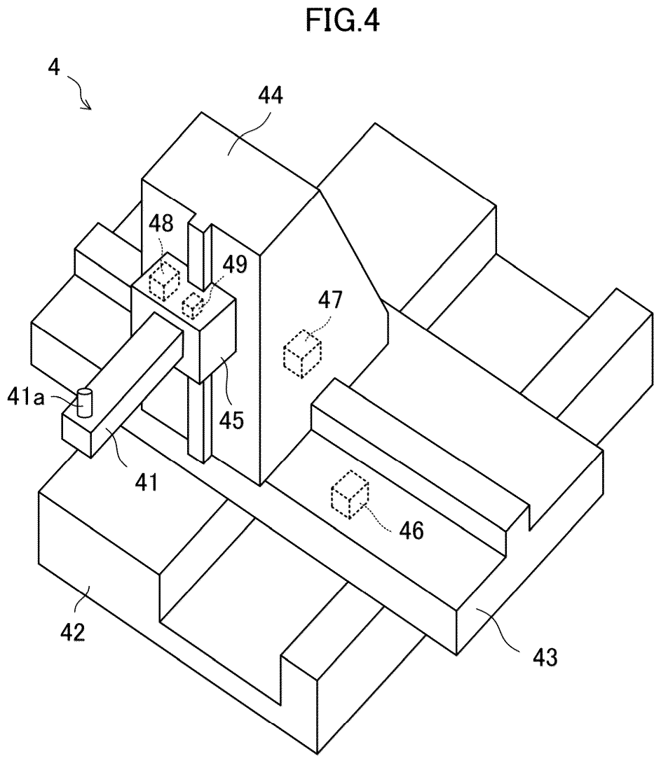

As illustrated in FIG. 4, the locator 4 includes a base 42 that is fixed to the floor, a first stage 43 that moves in the left-right direction, a second stage 44 that moves in the front-rear direction, and a third stage 45 that moves in the up-down direction. The arm 41 is connected to the third stage 45.

The first stage 43 is operated by a first motor 46. The second stage 44 is operated by a second motor 47. The third stage 45 is operated by a third motor 48. The second stage 44, the third stage 45, and the arm 41 move in the left-right direction as the first stage 43 moves in the left-right direction. The third stage 45 and the arm 41 move in the front-rear direction as the second stage 44 moves in the front-rear direction. The arm 41 moves in the up-down direction as the third stage 45 moves in the up-down direction. The first motor 46, the second motor 47, and the third motor 48 each may be a DC motor or an AC motor.

In the flow of movement of the first stage 43, the second stage 44, and the third stage 45 from the base 42 to the arm 41, the first motor 46, the second motor 47, and the third motor 48 are disposed in members on the relatively distal end side, where the base 42 side is the proximal end side and the arm 41 side is the distal end side. Take the base 42 and the first stage 43 for example. When the first stage 43 moves on the base 42, the arm 41 moves together with the first stage 43. Thus, the base 42 corresponds to a member on the proximal end side, and the first stage 43 corresponds to a member on the distal end side. The first motor 46 is disposed on the first stage 43, which is a member on the distal end side. The second motor 47 is disposed on the second stage 44, and the third motor 48 is disposed on the third stage 45. The first motor 46, the second motor 47, and the third motor 48 may be disposed on members on the relatively proximal end side. More specifically, in relation to the base 42 and the first stage 43, the first motor 46 may be disposed on the base 42. In relation to the first stage 43 and the second stage 44, the second motor 47 may be disposed on the first stage 43. In relation to the second stage 44 and the third stage 45, the third motor 48 may be disposed on the second stage 44. When the first motor 46, the second motor 47, and the third motor 48 are disposed on members on the relatively proximal end side, the first stage 43, the second stage 44, and the third stage 45 can be moved by operating a ball-screw drive mechanism or a belt drive mechanism using the first motor 46, the second motor 47, and the third motor 48.

When the body 11 is conveyed, the locators 4 operate the first stage 43, the second stage 44, and the third stage 45, and connect the pin 41a with the body 11. The locators 4 move the third stage 45 upward with the pin 41a and the body 11 connected to each other. The arm 41 of the locator 4 supports the body 11 from below with the body 11 lifted above the carriage 14. The locator 4 operates the first stage 43, the second stage 44, and the third stage 45 to align the body 11 with the body 11 supported. The system controller 16 calculates the movement amounts of the stages 43, 44, and 45 on the basis of the images acquired by the external camera 191 and calculation results of the monitoring device 30, which will be described later.

The current value supplied to the third motor 48 is acquired by a current sensor 49. The detected current value acquired by the current sensor 49 is sent to the monitoring device 30, which will be described later. When the third motor 48 is a DC motor, the detected current value is the degree of the current itself supplied to the third motor 48. When the third motor 48 is an AC motor, the detected current value is the degree of the amplitude of the current supplied to the third motor 48. When the third motor 48 is an AC motor, the current sensor 49 may acquire a current value of the q-axis current.

### (Monitoring System)

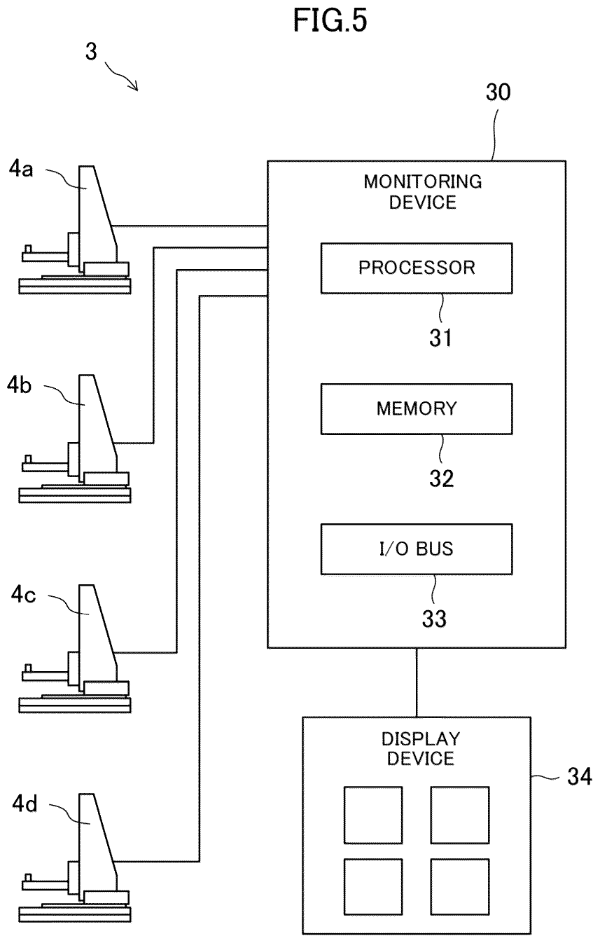

The third motor 48 of each of the four locators 4 is monitored by the monitoring system 3. The monitoring system 3 monitors a load on the third motor 48. As illustrated in FIG. 5, the monitoring system 3 includes a monitoring device 30 and a display device 34. The display device 34 is not an essential element of the monitoring system 3.

The monitoring device 30 includes a processor 31, a memory 32, and an I/O bus 33. The processor 31 includes at least one CPU. The processor 31 includes one or more chips. The memory 32 includes a random access memory (RAM) and a read only memory (ROM). The memory 32 is, for example, a nonvolatile memory. The I/O bus 33 is an input/output bus that inputs/outputs electrical signals to/from the processor 31.

The monitoring device 30 is electrically connected to the current sensors 49 of the first locator 4a, the second locator 4b, the third locator 4c, and the fourth locator 4d. The monitoring device 30 acquires detected current values from the current sensors 49 of the first locator 4a, the second locator 4b, the third locator 4c, and the fourth locator 4d, via the I/O bus 33. The monitoring device 30 is electrically connected to the system controller 16. The monitoring device 30 acquires detection results of the sensor 20 via the system controller 16.

The processor 31 calculates a comparison value for each of the locators 4 by comparing the detected current value with a representative value. The representative value is in the same unit or dimension as the detected current value, and is the detected current value itself or a parameter calculated from the detected current value. For example, the representative value is a current value supplied to the third motor 48 when the master workpiece is aligned by the locators 4 in the same manufacturing line. Specifically, the representative value is a detected current value acquired by the current sensor 49 when the master workpiece is supported from below by the arm 41 with the alignment of the master workpiece completed. The state where the alignment is completed is the state where the master workpiece is in parallel to the conveyance path 15. The representative value in this case corresponds to a reference current value when the locators 4 perform the alignment of the workpiece. The representative value is set for each of the locators 4. The memory 32 stores the current value as a representative value for each of the locators 4.

The processor 31 calculates a ratio between the detected current value and the representative value as the comparison value. The processor 31 calculates the comparison value by the equation:

$$Comparison Value = ( Detected Current Value / Representative Value ) \times 100.$$

For example, the processor 31 regards the comparison value as 100% when the detected current value is equal to the representative value, and regards the comparison value as 50% when the detected current value is half of the representative value. The processor 31 calculates a value exceeding 100%, such as 120%, as the comparison value when the detected current value is larger than the representative value. The processor 31 monitors the comparison value for the four locators 4 as a whole.

The detected current value represents the load on the third motor 48. The comparison value reflects a change in the load on the third motor 48. The processor 31 calculates the comparison value for each locator 4 so that the monitoring system 3 monitors the load balance of the four locators 4 as a whole.

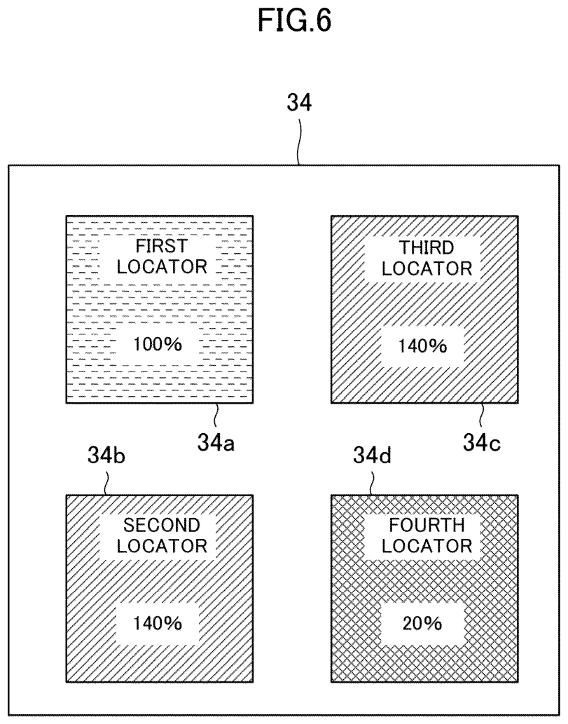

As illustrated in FIG. 6, the display device 34 shows the comparison values calculated by the monitoring device 30 for the respective locators 4 in the same arrangement as that of the locators 4 when the work area 13 is viewed in plan view. Specifically, the display screen of the display device 34 shows a first display area 34a on the upper left side, a second display area 34b on the lower left side, a third display area 34c on the upper right side, and a fourth display area 34d on the lower right side when the display screen is viewed from the front. The first display area 34a displays the comparison value of the first locator 4a, the second display area 34b displays the comparison value of the second locator 4b, the third display area 34c displays the comparison value of the third locator 4c, and the fourth display area 34d displays the comparison value of the fourth locator 4d. The display device 34 displays the comparison values as well as the names and the identification numbers of the respective locators 4.

The display device 34 changes the color of the display area according to the degree of the comparison value. For example, the display device 34 displays the comparison value in green when the comparison value is equal to or higher than a first threshold value and is less than a second threshold value which is larger than the first threshold value. The display device 34 displays the comparison value in yellow when the comparison value is less than the first threshold value. The display device 34 displays the comparison value in red when the comparison value is equal to or larger than the second threshold value. Each color is an example, and the other colors may be set. The first threshold value is not limited to particular values and is, for example, 90%. The second threshold value is not limited to particular values and is, for example, 110%.

The monitoring device 30 acquires the detected current value from the current sensor 49 at predetermined time intervals and calculates the comparison value by the processor 31. The monitoring device 30 updates what is displayed on the display device 34 every time the comparison value is calculated.

### (Flowchart)

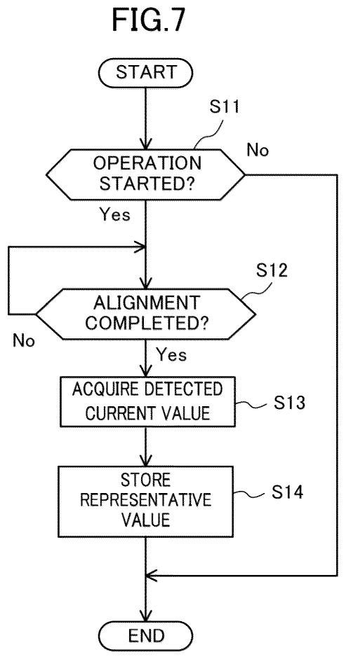

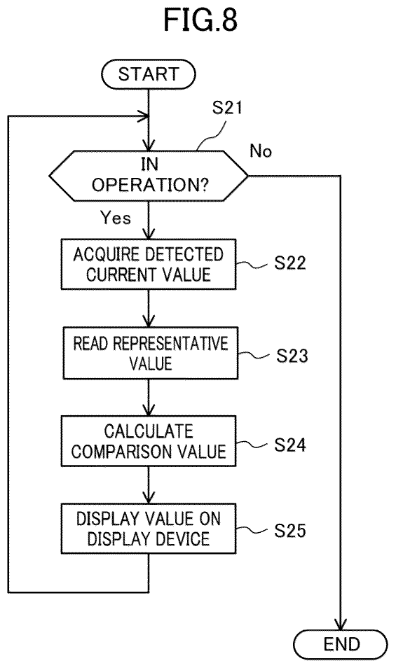

Next, a process of monitoring the comparison value by the monitoring system 3 will be described with reference to FIGS. 7 and 8. The process described below is stored as software in the form of a program in the memory 32 of the monitoring device 30. The processor 31 of the monitoring device 30 reads the program from the memory 32 and executes the process.

First, the process of acquiring the representative value will be described with reference to FIG. 7. The monitoring device 30 executes the flowchart of FIG. 7 when the robot system 1 is powered on and the conveyance of the master workpiece is started. The monitoring device 30 executes the flowchart of FIG. 7 also when the master workpiece is conveyed again for changing applications of the workpiece and checking the operation of the locator 4.

In Step S11, the monitoring device 30 determines whether or not each locator 4 has started operation. The monitoring device 30 determines whether or not each locator 4 is in operation on the basis of the signal from the sensor 20. The process in FIG. 7 proceeds to Step S12 if YES where the locator 4 has started the operation. The monitoring device 30 ends the process if NO where the locator 4 has not started the operation.

In Step S12, the monitoring device 30 determines whether or not the alignment of the master workpiece has been completed. The monitoring device 30 determines whether or not the alignment is completed on the basis of the image acquired by the external camera 191. The state where the alignment is completed is the state where the master workpiece is in parallel to the conveyance path 15. The process proceeds to Step S13 if YES where the alignment of the master workpiece has been completed. The process returns to Step S12 if NO where the alignment of the master workpiece has not been completed.

In Step S13, the monitoring device 30 acquires detected current values from the four current sensors 49 via the I/O bus 33.

Next, in Step S14, the monitoring device 30 stores the detected current values acquired in Step S13 in the memory 32 for the respective locators 4 as representative values of the respective locators 4.

The monitoring device 30 ends the process after Step S14.

Next, a process of monitoring the comparison value by the monitoring device 30 will be described with reference to FIG. 8.

First, in Step S21, the monitoring device 30 determines whether or not each locator 4 is in operation. The monitoring device 30 determines whether or not each locator 4 is in operation on the basis of the signal from the sensor 20. The process in FIG. 8 proceeds to Step S22 if YES where each locator 4 is in operation. The monitoring device 30 ends the process if NO where each locator 4 is not in operation.

In Step S22, the monitoring device 30 acquires detected current values from the four current sensors 49 via the I/O bus 33.

Next, in Step S23, the monitoring device 30 reads the representative value from the memory 32. The processor 31 reads the representative value stored for each of the four locators 4.

Next, in Step S24, the monitoring device 30 compares the detected current value with the representative value and calculates the comparison value for each locator 4.

Next, in Step S25, the monitoring device 30 sends the control signal to the display device 34 so that the display device 34 displays the calculated comparison value for each locator 4.

After the Step S25, the process returns to Step S21. The monitoring device 30 continues to monitor the comparison value until the determination in Step S21 comes to NO.

### (Effects and Advantages)

The monitoring system 3 monitors the comparison value relative to the current value of the third motor 48 for each locator 4. The current value of the third motor 48 corresponds to the load on the third motor 48. The monitoring system 3 calculates the comparison value of the load for each locator 4 and monitors the locators 4 as a whole. Thus, the cause of the change in load on the third motor 48 can be easily clarified.

For example, as illustrated in FIG. 6, the comparison values for the second locator 4b and the third locator 4c exceed the second threshold value, and the comparison values for the first locator 4a and the fourth locator 4d are equal to or lower than the first threshold value. In such a case, the system controller 16 can estimate that the change in load is due to the fact that the body 11 is not in a posture in parallel with the conveyance path 15 but in a posture tilted toward the second locator 4b and the third locator 4c. The monitoring device 30 sends signals showing the respective current comparison values to the system controller 16. The system controller 16 may control the locators 4 so that the comparison values of the respective locators 4 are equal to or higher than the first threshold value and less than the second threshold value in order to align the body 11. In other words, the monitoring device 30 monitors the comparison values of the locators 4 as a whole to align the body 11.

The body 11 is conveyed to the work area 13 by the AMR 6, so that the posture of the body 11 is likely to be misaligned when moved to the work area 13. The external camera 191 can easily detect the misalignment of the posture of the body 11 in the horizontal direction, but cannot easily detect the misalignment of the posture of the body 11 in the up-down direction. The monitoring system 3 can represent the misalignment of the posture of the body 11 in the up-down direction as a change in load on the third motor 48. The monitoring system 3 enhances the accuracy of the alignment of the body 11.

For example, the comparison value for the first locator 4a only may be frequently equal to or higher than the second threshold value, even through the body 11 is in parallel with the conveyance path 15. In such a case, the monitoring device 30 can estimate that the change in load is due to deterioration of the third motor 48 of the first locator 4a. In other words, the monitoring device 30 monitors the comparison values for the locator 4 as a whole, so that the quality of the third motor 48 of each locator 4 can be controlled.

For example, the comparison values for the first locator 4a, the second locator 4b, and the third locator 4c may be equal to or higher than the first threshold value and less than the second threshold value, but the comparison value for the fourth locator 4d may be less than the first threshold value. Such a case means that only the load on the fourth locator 4d is small. As mentioned above, when the alignment of the body 11 is insufficient, load on some locators 4 decrease, but load on the other locators 4 increase. When the third motor 48 of the fourth locator 4d is deteriorated, the load becomes large. Thus, the monitoring device 30 can estimate that the change in load on the fourth locator 4d is caused by a problem of the body 11 itself, for example, a shape defect of the body 11. In other words, the monitoring device 30 monitors the comparison values of the locators 4 as a whole to control the quality of the body 11.

The representative value is a current value supplied to the third motor 48 when the master workpiece is aligned. With the master workpiece aligned, the load on the locator 4 can be regarded as an ideal load. Since the comparison value indicates a change from an ideal load, monitoring the comparison value for each locator 4 makes it easier to grasp the cause of the change in load.

The arm 41 supports the body 11 from below, and the third motor 48 moves the arm 41 in the up-down direction. The monitoring device 30 acquires a current value when the arm 41 supports the body 11. The load on the third motor 48 is a load in the up-down direction, reflects the weight of the body 11 at the support position, and thus is likely to reflect the influence of the posture and quality of the body 11. The monitoring device 30 calculates the comparison value for load on each third motor 48, so that the cause of the change in load is easily grasped.

The locator 4 supports the body 11 to be conveyed to the work area 13 by the AMR 6 while the robots 2 are in operation on the body 11. By monitoring the load on the locators 4 as a whole during the operation of the robots 2, the change in the posture of the body 11 during the operation is grasped by the monitoring system 3. The monitoring system 3 enhances the accuracy of alignment of the body 11 during the operation of the robot 2.

The monitoring device 30 further includes a display device 34 that displays the comparison value calculated by the processor 31 for each locator 4 in the same arrangement as that of the locators 4. The operator can immediately understand which locator 4 has an excessively high load and which locator has an excessively low load by viewing the display device 34. The operator can easily grasp the cause of the change in the load.

### (First Variation)

The first variation is different in the process of monitoring the comparison value. Specifically, in the first variation, the representative value is an average value of current values supplied to the third motors 48 with bodies 11 in the same type aligned. In particular, the representative value is an average value of current values supplied to the third motors 48 with the alignment of the body 11 in the front-rear direction and the left-right direction completed.

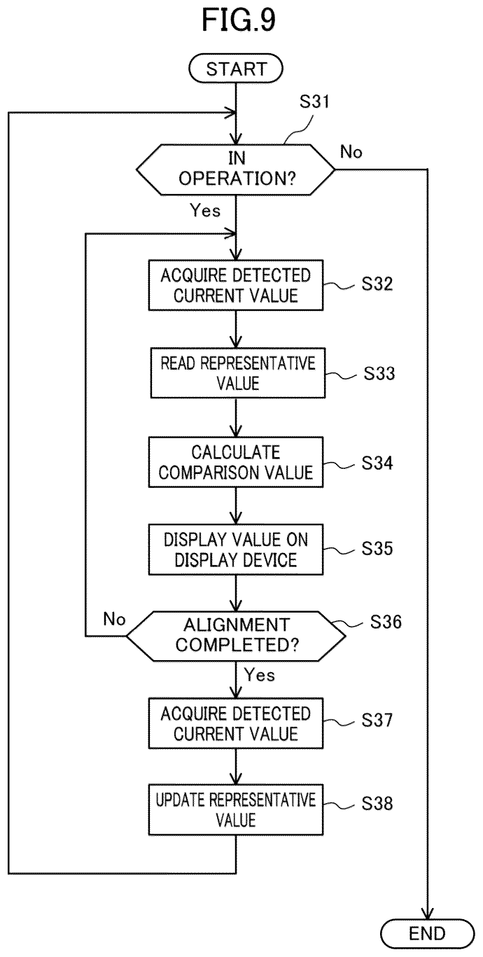

FIG. 9 is a flowchart illustrating a process of monitoring a comparison value by a monitoring device 30 according to a first variation.

First, in Step S31, the monitoring device 30 determines whether or not each locator 4 is in operation. The monitoring device 30 determines whether or not each locator 4 is in operation on the basis of the signal from the sensor 20. The process in FIG. 9 proceeds to Step S32 if YES where each locator 4 is in operation. The monitoring device 30 ends the process if NO where each locator 4 is not in operation.

In Step S32, the monitoring device 30 acquires detected current values from the four current sensors 49 via the I/O bus 33.

Next, in Step S33, the monitoring device 30 reads the representative value from the memory 32. The monitoring device 30 reads the representative value stored for each of the four locators 4.

Next, in Step S34, the monitoring device 30 compares the detected current value with the representative value and calculates the comparison value for each locator 4.

Next, in Step S35, the monitoring device 30 sends the control signal to the display device 34 and displays the calculated comparison value for each locator 4.

Next, in Step S36, the monitoring device 30 determines whether or not the alignment of the body 11 has been completed. The monitoring device 30 determines whether or not the alignment is completed on the basis of the image acquired by the external camera 191 and the comparison value calculated. The state where the alignment is completed is the state where the body 11 is in parallel to the conveyance path 15. The process proceeds to Step S37 if YES where the alignment of the body 11 has been completed. The process returns to Step S32 if NO where the alignment of the body 11 has not been completed.

In Step S37, the monitoring device 30 acquires detected current values from the four current sensors 49 via the I/O bus 33.

Next, in Step S38, the monitoring device 30 updates the representative value stored in the memory 32 on the basis of the detected current value acquired in Step S37. The representative value is an average value of the detected current values acquired in Step S37.

After Step S38, the process returns to Step S31. The monitoring device 30 continues to monitor the comparison value until the determination in Step S31 comes to NO.

In the first variation, the representative value reflects the current values supplied to the third motor 48 with the alignment of the actual body 11 completed. Using the representative value in the first variation, the change in the posture and the quality of the body 11 are easily reflected as a change in the load. The operator can easily grasp the cause of the change in the load.

### (Second Variation)

The second variation is different in the process of monitoring the comparison value. Specifically, in the second variation, the representative value is one current value selected from the current values acquired by the I/O bus 33 at the same timing. For example, when the current value of the first locator 4a is selected as the representative value, the comparison value is the ratio to the current value supplied to the third motor 48 of the first locator 4a. The specific locator for which the detected current value is set as a representative value is set in advance. The comparison value of the specific locator will always be 100%. The “same timing” does not have to be strictly simultaneous, and can be within a predetermined time range.

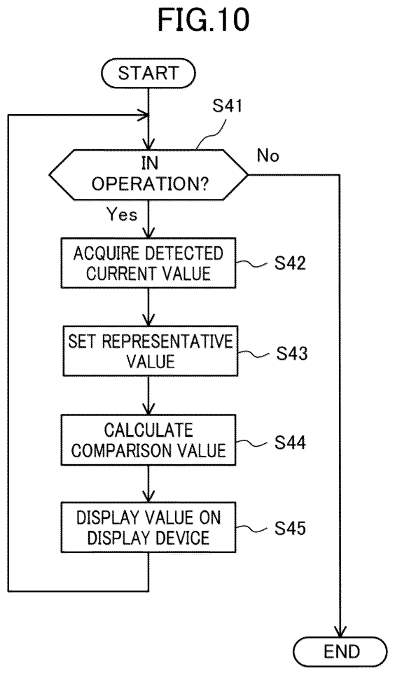

FIG. 10 illustrates a process of monitoring the comparison value by a system controller 16 according to the second variation.

First, in Step S41, the monitoring device 30 determines whether or not each locator 4 is in operation. The monitoring device 30 determines whether or not each locator 4 is in operation on the basis of the signal from the sensor 20. The process in FIG. 10 proceeds to Step S42 if YES where each locator 4 is in operation. The monitoring device 30 ends the process if NO where each locator 4 is not in operation.

In Step S42, the monitoring device 30 acquires detected current values from the four current sensors 49 via the I/O bus 33.

Next, in Step S43, the monitoring device 30 sets the detected current value acquired from the specific locator as the representative value.

Next, in Step S44, the monitoring device 30 compares the detected current value with the representative value and calculates the comparison value for each locator 4.

Next, in Step S45, the monitoring device 30 sends the control signal to the display device 34 and displays the calculated comparison value for each locator 4.

After Step S45, the monitoring device 30 returns to Step S41. The monitoring device 30 continues to monitor the comparison value until the determination in Step S41 comes to NO.

In the second variation, the loads on the third motors 48 of the respective locators 4 are compared, so that the deterioration state of each third motor 48 is easily reflected. For example, when the third motors 48 of the locators other than the specific locator are deteriorated, the comparison values of the locators becomes high. Thus, it can be determined that the third motors 48 are deteriorated. On the other hand, when the third motor 48 of the specific locator is deteriorated, the comparison values for the other locators become low. Thus, it can be determined that the third motor 48 of the specific locator is deteriorated.

### (Other Variations)

The monitoring device 30 mentioned above acquires the detected current value of the current sensor 49. In the monitoring device 30, the locator controller 18 may acquire the current values supplied to the third motors 48 instead of the detected current value of the current sensor 49. In such a case, the current sensor 49 is not required.

The monitoring device 30 mentioned above calculates the ratio of the detected current value to the representative value as a comparison value. The monitoring device 30 may calculate the rate of change in the detected current value relative to the representative value as a comparison value. In such a case, the processor 31 of the monitoring device 30 calculates a comparison value by using the equation:

$$Comparison Value = \{ ( Detected Current Value - Representative Value ) / Representative Value \} \times 100.$$

The display device 34 displays a minus sign before the numerical value when the detected current value is smaller than the representative value.

The monitoring system 3 described above monitors the load on the third motor 48. A target to be monitored by the monitoring system 3 is not necessarily the third motor 48. For example, the monitoring system 3 may monitor the load on the first motor 46 and the load on the second motor 47. The display device 34 may display the comparison value for the first motor 46 and the comparison value for the second motor 47 instead of the comparison value for the third motor 48 or in addition to the comparison value for the third motor 48.

The monitoring device 30 described above is separate from the system controller 16. The monitoring device 30 may be part of the system controller 16. The display device 34 is also part of the system controller 16. The monitoring device 30 may be incorporated in the locator controller 18.

In the robot system 1 described above, the locator 4 aligns the body 11 in the horizontal plane. The AMR 6 may be used to align the body 11 in the horizontal plane in the work area 13. In such a case, the monitoring system 3 monitors the load balance of the locators 4 as a whole, making it easier to grasp that the cause of the change in the load is the quality of the body 11 or the deterioration of the third motor 48.

The operation that the robot system 1 disclosed herein including the monitoring system 3 performs in the manufacturing line 10 is not limited to welding. The workpiece on which the robot system 1 performs the operation is not limited to the body 11 of the automobile. The monitoring system 3 is not limited to being applied to the manufacturing line 10 of the automobile.

The functionality of the elements disclosed herein may be implemented using circuitry or processing circuitry which includes general purpose processors, special purpose processors, integrated circuits, ASICs (“Application Specific Integrated Circuits”), conventional circuitry and/or combinations thereof which are configured or programmed to perform the disclosed functionality. Processors are considered processing circuitry or circuitry as they include transistors and other circuitry therein. The processor may be a programmed processor which executes a program stored in a memory. In the disclosure, the circuitry, units, or means are hardware that carry out or are programmed to perform the recited functionality. The hardware may be any hardware disclosed herein or otherwise known which is programmed or configured to carry out the recited functionality. When the hardware is a processor which may be considered a type of circuitry, the circuitry, means, or units are a combination of hardware and software, the software being used to configure the hardware and/or processor.

### (Aspects)

The above embodiments are specific examples of the following aspects.

### (First Aspect)

A monitoring system (3) including:
locators (4a, 4b, 4c, 4d) that each have an arm (41) moved by a motor (48) and align, at the respective positions, workpiece (11) conveyed to a work area (13); and
a monitoring device (30) that calculates a comparison value for each of the locators (4a, 4b, 4c, 4d) by comparing a current value supplied to the motor (48) with a representative value set for each of the locators (4a, 4b, 4c, 4d) and associated with the current value.

The monitoring system (3) calculates the comparison value of load for each of the locators (4a, 4b, 4c, 4d) and monitors a load balance of the locators (4a, 4b, 4c, 4d) as a whole. The monitoring system (3) allows the operator to easily clarify the cause of the change in load on the motor (48).

### (Second Aspect)

The monitoring system (3) of the first aspect, wherein
the representative value is the current value when a master workpiece is aligned.

With the master workpiece aligned, the load on the locator (4) can be regarded as an ideal load. The comparison value can represent the change from the ideal load. The operator can easily grasp the cause of the change in the load.

### (Third Aspect)

The monitoring system (3) of the first aspect, wherein
the workpiece (11) includes workpieces (11), and the representative value is an average value of the current values when the workpieces (11) in the same type are aligned.

The change in posture or quality of each workpiece (11) is likely to be reflected as a change in the load. The operator can easily grasp the cause of the change in the load.

### (Fourth Aspect)

The monitoring system (3) of the first aspect, wherein
the representative value is one current value selected from the current values for the respective locators (4a, 4b, 4c, 4d), supplied at the same timing.

The loads on the third motors 48 for the respective locators (4a, 4b, 4c, 4d) are compared, so that the deterioration states of the motors (48) are easily reflected. The operator can easily grasp the cause of the change in the load.

### (Fifth Aspect)

The monitoring system (3) of any one of the first aspect to the fourth aspect, wherein
the arm (41) supports the workpiece (11) from below,
the motor (48) moves the arm (41) in the up-down direction, and
the monitoring device (30) acquires the current value when the arm (41) supports the workpiece (11).

The load on the motor (48) reflects the weight of the workpiece (11) at the support position, and thus is likely to reflect the influence of the posture and quality of the workpiece (11). The monitoring device (30) calculates the comparison value for the load of each motor (48), which allows the operator to easily grasp the cause of the change in the load.

### (Sixth Aspect)

The monitoring system (3) of the fifth aspect, wherein
the locators (4a, 4b, 4c, 4d) support the workpiece (11) conveyed to the work area (13) by a carrier (6) while a robot (2) is in operation on the workpiece (11).

The load balance for the locators (4a, 4b, 4c, 4d) as a whole can be monitored while the robot (2) is in operation. When the support of the workpiece (11) is insufficient and the posture of the workpiece (11) changes during the operation of the robot (2), the monitoring system (3) can grasp the change. The monitoring system (3) enhances the accuracy of alignment of the workpiece (11) during the operation of the robot (2).

### (Seventh Aspect)

The monitoring system (3) of any one of the first to sixth aspects, further comprising:
a display device (34) that displays the comparison value calculated by the monitoring device (30) for each of the locators (4a, 4b, 4c, 4d) in the same arrangement as that of the locators (4a, 4b, 4c, 4d).

The operator can immediately understand which locator (4a, 4b, 4c, 4d) has an excessively high load and which locator (4a, 4b, 4c, 4d) has an excessively low load by viewing the display device (34). The operator can easily grasp the cause of the change in the load.

What is claimed is:

1. A monitoring system comprising:
locators that each have an arm moved by a motor and align, at the respective positions, a workpiece conveyed to a work area; and
a monitoring device that calculates a comparison value for each of the locators by comparing a current value supplied to the motor with a representative value set for each of the locators and associated with the current value.

2. The monitoring system of claim 1, wherein
the representative value is the current value when a master workpiece is aligned.

3. The monitoring system of claim 1, wherein
the workpiece comprises workpieces, and the representative value is an average value of the current values when the workpieces in the same type are aligned.

4. The monitoring system of claim 1, wherein
the representative value is one current value selected from the current values for the respective locators supplied at the same timing.

5. The monitoring system of claim 1, wherein
the arm supports the workpiece from below,
the motor moves the arm in an up-down direction, and
the monitoring device acquires the current value when the arm supports the workpiece.

6. The monitoring system of claim 5, wherein
the locators support the workpiece conveyed to the work area by a carrier while a robot is in operation on the workpiece.

7. The monitoring system of claim 1, further comprising:
a display device that displays the comparison value calculated by the monitoring device for each of the locators in the same arrangement as that of the locators.
